(19) United States
(12) Patent Application Publication
(10) Pub. No.: US 2007/0215962 A1
(43) Pub. Date: Sep. 20, 2007

(54) Microelectromechanical system assembly and method for manufacturing thereof

(75) Inventors: Anthony Minervini, Palos Hills, IL (US); Peter V. Loeppert, Hoffman Estates, IL (US); William A. Ryan, Villa Park, IL (US)

Correspondence Address: FITCH EVEN TABIN AND FLANNERY, 120 SOUTH LA SALLE STREET, SUITE 1600, CHICAGO, IL, 60603-3406, US

(73) Assignee: Knowles Elecronics, LLC, Itasca, IL (US)

(21) Appl. No.: 11/384,599

(22) Filed: Mar. 20, 2006

(51) Int. Cl. H01L 29/82

(52) U.S. Cl. 257/414

(57) ABSTRACT

A microelectromechanical system (MEMS) assembly comprises a MEMS transducer, an integrated circuit (IC), and a substrate. The integrated circuit and the MEMS transducer are being electrically coupled to the substrate. The substrate may be a single layer or multiple layers. A coupling circuit resides in the substrate and may comprise a low pass filter (LPF) to provide a path to ground for undesirable co-propagating RF signals while allow direct current (DC) or low frequency signals to pass through the IC.

### TECHNICAL FIELD

This patent generally relates to microelectromechanical system (MEMS) packages, and more particularly, to MEMS packages providing radio frequency (RF) shielding against radiation and interference.

### BACKGROUND

Mobile communication technology has progressed rapidly in recent years. Consumers are increasingly using electronic devices such as computers (e.g., desktops, laptops, notebooks, tablets, hand-held computers, and Personal Digital Assistants (PDAs)), communication devices (e.g., cellular phones, web-enabled cellular telephones, cordless phones, and pagers), computer-related peripherals (e.g., printers, scanners, and monitors), entertainment devices (e.g., televisions, radios, stereos, tape and compact disc players, digital cameras, cameras, video cassette recorders, and MP3 (Motion Picture Expert Group, Audio Layer 3) players), listening devices (e.g., hearing aids) and the like. In the field of consumer electronic devices, there is incessant competitive pressure among manufacturers to reduce the device size, tighten component spacing, reduce cost, and improve the reliability of these devices.

Electronic devices often operate where various forms of electromagnetic interference (EMI) (e.g., radio frequency (RF) noise, crosstalk, radio frequency interference (RFI), and all other forms of radiation) are present and some previous systems have attempted to minimize the effects this interference. For instance, some previous approaches have used surface mounted components such as resistors, capacitors, and inductors to construct low pass filters (LPFs) in order to shield the device from radio frequency interference (RFI).

Unfortunately, these previous approaches have proven unsatisfactory for a variety of reasons. For instance, since surface mounted components were used, an increased number of discrete components were required thereby making it difficult to find adequate space for these components and still maintain the small-scale dimensions required for the device. Even if the space were found to place all the components, adequate spacing between the components was often difficult or impossible to achieve given the tolerances required and using previous automated placement equipment. Electrical performance and reliability also became a problem with the increased component count and spacing limitations. In addition, manufacturing costs became significantly increased by the use of higher number of components, thereby making the final product more expensive for the customer.

### BRIEF DESCRIPTION OF THE DRAWINGS

For a more complete understanding of the disclosure, reference should be made to the following detailed description and accompanying drawings wherein:

FIG. 1 is a perspective view illustrating a MEMS assembly according to the present invention;

FIG. 2 is a cross-sectional view of the MEMS assembly shown in FIG. 1 according to the present invention;

FIGS. 3A-3H are cross-sectional views of embedded integral components in a substrate according to the present invention;

FIG. 4A is a cross-sectional view of a portion of the MEMS assembly of FIG. 2, without a housing being illustrated, according to the present invention;

FIG. 4B is a top-down view of the MEMS assembly shown in FIG. 4A according to the present invention;

FIG. 5A is a cross-sectional view of a portion of a MEMS assembly shown in FIG. 2 according to the present invention;

FIG. 5B is a top-down view of the MEMS assembly shown in FIG. 5A according to the present invention;

FIG. 6A is a cross-sectional view of a portion of a MEMS assembly shown in FIG. 2 according to the present invention;

FIG. 6B is a top-down view of the MEMS assembly shown in FIG. 6A according to the present invention;

FIG. 7A is a cross-sectional view of a portion of a MEMS assembly shown in FIG. 2 according to the present invention;

FIG. 7B is a top-down view of the MEMS assembly shown in FIG. 7A according to the present invention;

FIG. 8A is a cross-sectional view of a portion of a MEMS assembly shown in FIG. 2 according to the present invention;

FIG. 8B is a top-down view of the MEMS assembly shown in FIG. 8A according to the present invention;

FIG. 9A is a cross-sectional view of a portion of a MEMS assembly shown in FIG. 2 according to the present invention;

FIG. 9B is a top-down view of the MEMS assembly shown in FIG. 9A according to the present invention;

FIG. 10A is a cross-sectional view of a portion of a MEMS assembly shown in FIG. 2 according to the present invention;

FIG. 10B is a top-down view of the MEMS assembly shown in FIG. 10A according to the present invention;

FIG. 11A is an exploded view of a portion of a MEMS assembly shown in FIG. 2 according to the present invention;

FIG. 11B is a cross-sectional view of the MEMS assembly shown in FIG. 11A according to the present invention;

FIG. 12A is a cross-sectional view of a portion of a MEMS assembly shown in FIG. 2 according to the present invention;

FIG. 12B is a top-down view of the MEMS assembly shown in FIG. 12A according to the present invention;

FIG. 13A is a cross-sectional view of a portion of a MEMS assembly shown in FIG. 2 according to the present invention; and

FIG. 13B is an exploded view of the MEMS assembly shown in FIG. 13A according to the present invention.

Skilled artisans will appreciate that elements in the figures are illustrated for simplicity and clarify. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

While the present disclosure is susceptible to various modifications and alternative forms, certain embodiments are shown by way of example in the drawings and these embodiments will be described in detail herein. It will be understood, however, that this disclosure is not intended to limit the invention to the particular forms described, but to the contrary, the invention is intended to cover all modifications, alternatives, and equivalents falling within the spirit and scope of the invention defined by the appended claims.

Microelectromechanical system (MEMS) assemblies and approaches for manufacturing these assemblies are provided. The assemblies provided possess small dimensions and are, consequently, suitable for inclusion in small and/or thin electronic devices. In this regard, these assemblies can be included in electronic devices such as computers (e.g., desktops, laptops, notebooks, tablets, hand-held computers, and Personal Digital Assistants (PDAs)), communication devices (e.g., cellular phones, web-enabled cellular telephones, cordless phones, and pagers), computer-related peripherals (e.g., printers, scanners, and monitors), entertainment devices (e.g., televisions, radios, stereos, tape and compact disc players, digital cameras, cameras, video cassette recorders, and MP3 (Motion Picture Expert Group, Audio Layer 3) players), and listening devices (e.g., hearing aids). Other examples of devices are possible. Furthermore, these assemblies significantly reduce or eliminate the effects of electromagnetic interference (EMI). Since these assemblies are small and easy to manufacture, manufacturing costs are reduced and reliability is enhanced.

In many of these embodiments, a MEMS assembly comprises a MEMS transducer, an integrated circuit, and a coupling circuit. The integrated circuit is electrically coupled to the MEMS transducer. The coupling circuit is electrically coupled to the integrated circuit and is adapted to reduce electromagnetic interference (EMI). In one example, the MEMS transducer is a microphone.

The MEMS assembly may further include a substrate and the substrate may include a first substrate layer and a second substrate layer. The second substrate layer may be attached to the first substrate layer and each of the substrate layers may define at least one conductive layer, one intermediate layer and/or one dielectric layer.

The coupling circuit may comprise any type of coupling circuit that reduces or eliminates EMI such as a low pass filter (LPF) circuit. In one example, the coupling circuit comprises at least one capacitor. In another example, the coupling circuit may further comprise one or more resistors, inductors, or combined resistors and inductors.

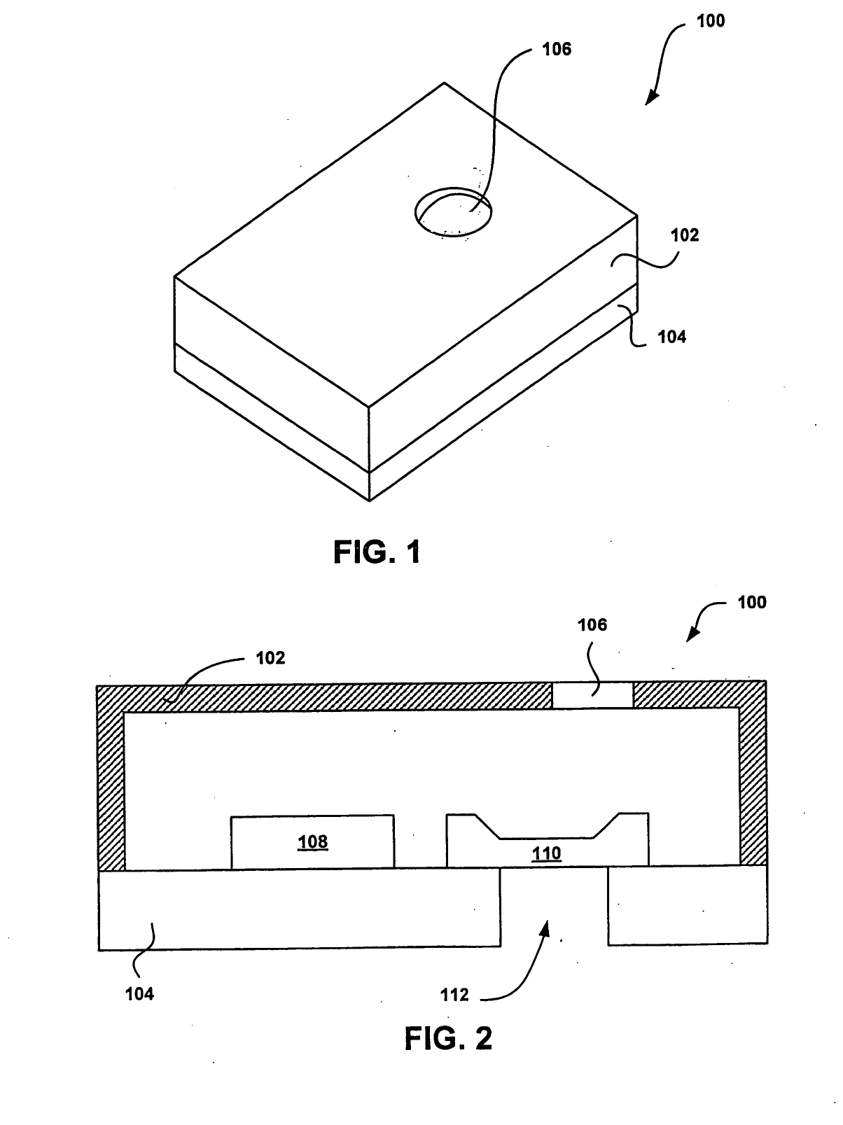

Turning now to the drawings and referring to FIG. 1, a perspective view of a microelectromechanical system (MEMS) assembly 100 is described. The MEMS assembly comprises a cover 102 and a substrate 104, which is attached to the cover 102 by any suitable method of attachment. The cover 102 protects the internal working components from light, electromagnetic interference (EMI), and physical damage as disclosed in U.S. patent application Ser. Nos. 10/921,747, 11/112,043, and 11/276,025, the disclosures of which are herein incorporated by reference in their entirety for all purposes. The MEMS assembly 100 may be a single acoustic port microphone or a two acoustic port microphone. For example, the MEMS assembly 100 may include a single port 106 or multiple ports 106 and 112 (see FIG. 2) depending on the desired applications. The aperture 106 is formed on the cover 102 using any suitable technique or method.

FIG. 2 illustrates a cross-sectional view of the MEMS assembly 100 as shown in FIG. 1. The MEMS assembly 100 further comprises an integrated circuit (IC) 108 and a transducer 110 housed within the cover 102. The transducer 110 is a silicon-based microphone such as a silicon condenser microphone as disclosed in U.S. Pat. No. 5,870,482, which is herein incorporated by reference in its entirety for all purpose. The acoustic port 112 may be formed by drilling through the substrate 104.

The substrate 104 can be formed from a printed circuit board (PCB), a flexible circuit, a ceramic substrate, a thin film multichip module substrate, or similar substrate material. Furthermore, the substrate 104 may be a rigid or flexible support for embedded electronic components. The substrate 104 is shown as having at least one layer. However, the substrate 104 may utilize multiple layers, and such examples are discussed in greater detail herein. In the example shown, the substrate 104 is a PCB.

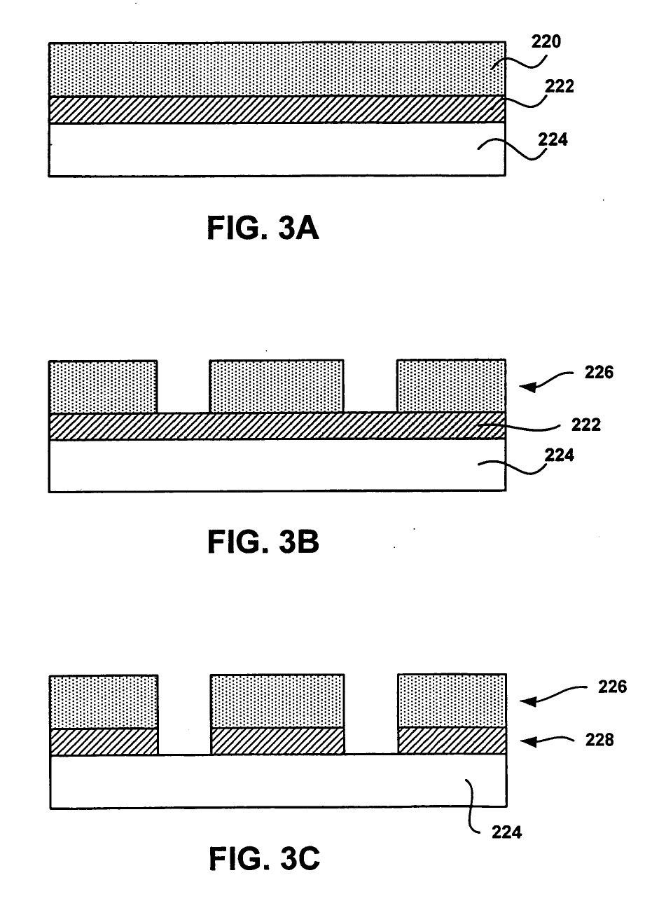

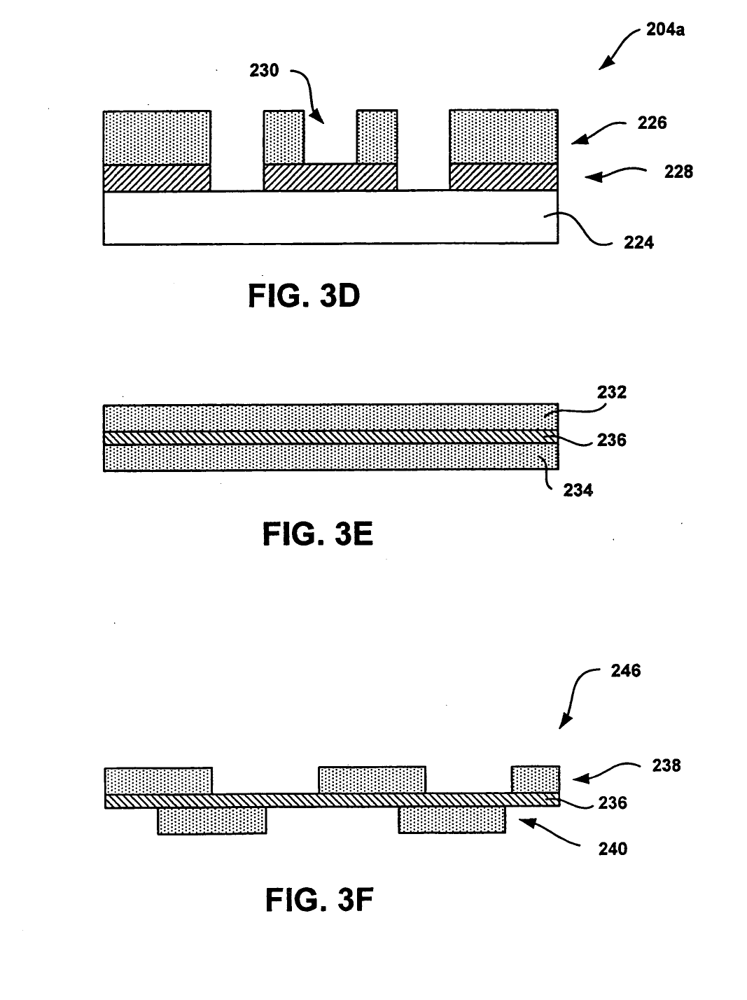

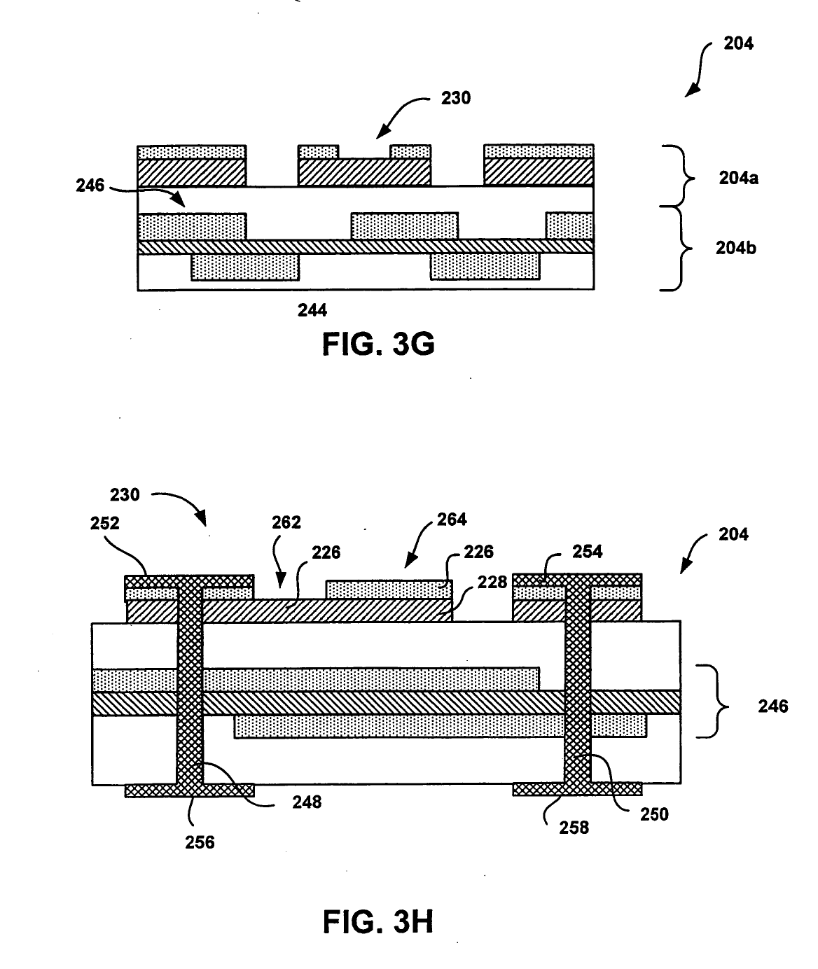

FIGS. 3A-3H describe the formation of embedded components in a PCB 204. Referring to FIGS. 3A-3D, a method for fabricating an embedded resistor 230 in a first PCB 204a is illustrated. A conductive layer 220, an intermediate layer 222, and an insulating layer 224 are attached together by lamination, vapor deposition, sputtering, evaporation, coating, electrodeposition, or plating, as depicted in FIG. 3A. The conductive layer 220 is coated with an etch resist material (not shown), exposed and developed, thereby forming an etched conducting pattern 226, as shown in FIG. 3B. A portion of the intermediate layer 222 exposed through the etched conducting pattern 226 is etched using any conventional etchant, thereby forming a substantially matching pattern 228, as shown in FIG. 3C. The etch conducting pattern 226 is further patterned and etched to expose a portion of the etched matching pattern 228, thereby forming at least one embedded resistor 230 in a first PCB 204a, as shown in FIG. 3D.

Referring to FIGS. 3E-3F, a method for fabricating an embedded capacitor 246 is illustrated. A pair of conductive layers 232 and 234 are attached to both sides of a dielectric layer 236 by lamination or any other suitable method of attachments, as shown in FIG. 3E. The conductive layers 232 and 234 are etched using any conventional etchant, thereby forming etched conducting patterns 238 and 240, as depicted in FIG. 3F. The combined etched conducting patterns 238 and 240 and the dielectric layer 236 constitute an embedded capacitor 246. The embedded capacitor 246 offers many benefits, for example, improved electrical performance, increased packaging density, improved reliability and potential cost reduction. Further, embedded capacitor 246 has a high capacitance and very low inductance that improves signal integrity, reduces power bus noise and reduces EMI. An optional insulating layer (not shown) may be attached to the embedded capacitor 246, forming a second substrate 204b (See FIG. 3G).

The conductive layers 220, 232, and 234 comprise a metal or combinations of alloys thereof that are able to conduct an electrical current. The conductive layers 220, 232 and 234 may be a single or multiple layers. The conductive layers 220, 232, and 234 may comprise either the same metal or may comprise different materials. In this example, the conductive layers 220, 232, and 234 are a copper material. Each conductive layer 220, 232, and 234 has a thickness of from about 0.1 to about 200 microns. The intermediate layer 222, also known as resistive foil (R-foil), is a nickel phosphorus (NiP) alloy that is resistive to current. The intermediate layer 222 has a thickness of from about 0.1 to about 200 microns.

The dielectric layer 236 comprises a solid material such as a thermosetting polymer, thermoplastic polymer, inorganic composition or a combination thereof. The dielectric layer 236 has a thickness of from about 0.1 to about 200 microns. The insulating layer 224 may be formed from a printed circuit board (PCB), a flexible circuit, a ceramic substrate, a thin film multichip module substrate, or similar substrate material. In the example shown, the insulating layer 224 is a FR-4 fiberglass reinforced epoxy resin.

Referring now to FIGS. 3G-3H, the first and second PCB layers 204a and 204b are laminated together forming a multilayer PCB 204. An optional plurality of plated through holes 248 and 250, also know as through-vias, are drilled through the substrate 204 by any conventional method for connecting selected traces, pads, or the like, to internal conductive layers or planes. An optional plurality of metalized pads 252, 254, 256, and 258 may be provided by plating and surrounding the through-vias 248 and 250.

There are several factors driving the trend to use embedded integral passive components over discrete passive components and embedded discrete active components over surface mounted discrete active components. Embedding integral passive components, such as capacitors, resistors, and inductors into a PCB (e.g., the PCB 204) allows for tightened component spacing, reduced via count and increased routing area. Further, having a PCB (e.g., the PCB 204) with embedded components (e.g., a capacitor-resistor) allows for a reduction in the board size and or board layers, improved reliability, performance, and RF immunity.

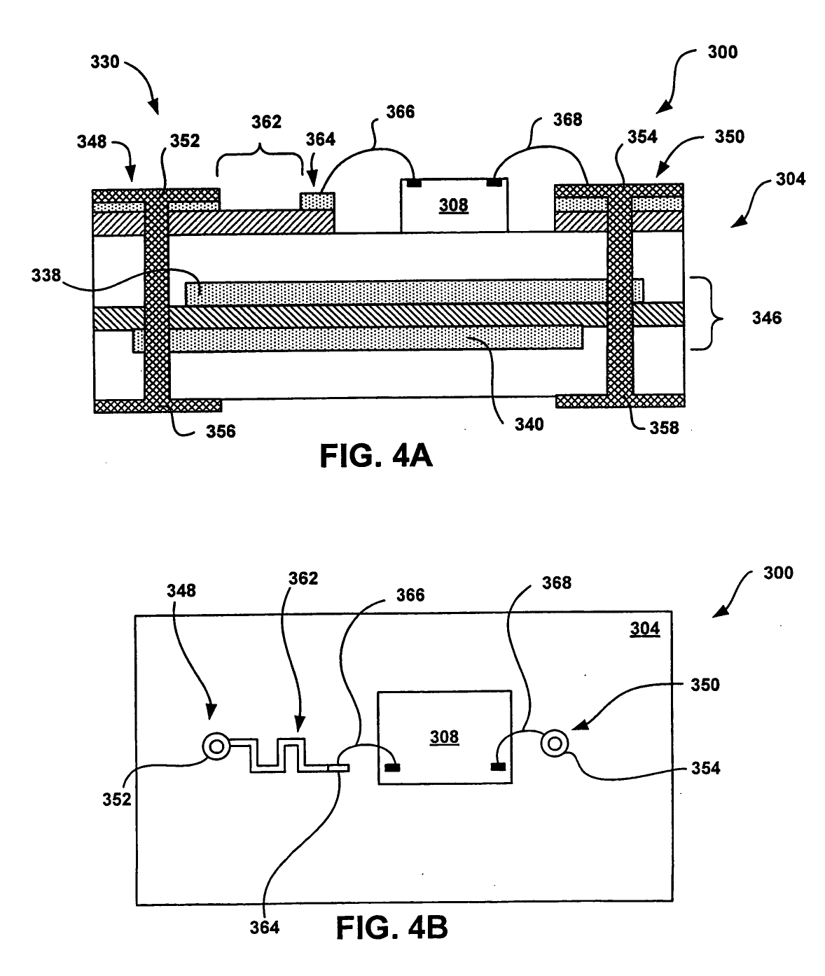

FIGS. 4A-4B illustrate an example of a MEMS assembly 300. The PCB 304 is similar in construction and function as the PCB 204 illustrated in FIGS. 3A-3H, and like elements are referred to using like reference numerals herein, for example 330 and 346 correspond to 230 and 246, respectively.

An IC 308 mounted on one surface of the substrate 304 may be connected to conductive pads 364 and 354. A first bond wire 366 is connected between the IC 308 and the bond pad 364 of the resistor portion 330. A long conductive trace 362 of the resistor portion 330 (connecting the bond pad 364 to a first through-via 348), may be in the form of a meandering spiral, L, and U shape and act as a resistor, an inductor, or both. A second bond wire 368 is provided to connect the IC 308 to a second through-via 350. The first and second through-vias 348 and 350 then connect the IC 308 for routing selected trace 362, pads 352 and 354, or the like, to internal conductive layers or planes 338, 340.

As shown in FIG. 4A, the first through-vias 348 is formed (e.g., drilled) through the PCB 304 to contact a conductive layer 340 and the second through-vias 350 is formed (e.g., drilled) through the PCB 304 to contact a conductive layer 338. A signal pad 356 and a ground pad 358 are attached to the opposite surface of the PCB 304 which is coupled to the conductive layers 338 and 340 by through-vias 348 and 350. A coupling circuit, also known as an embedded resistor-inductor/capacitor (RL/C) network 330, and 346, provides a path to ground for undesirable co-propagating RF signals while allow DC or low frequency signals to pass through the IC 308. In the example shown, the coupling circuit is a low pass filter (LPF). Other types of circuits may also be used.

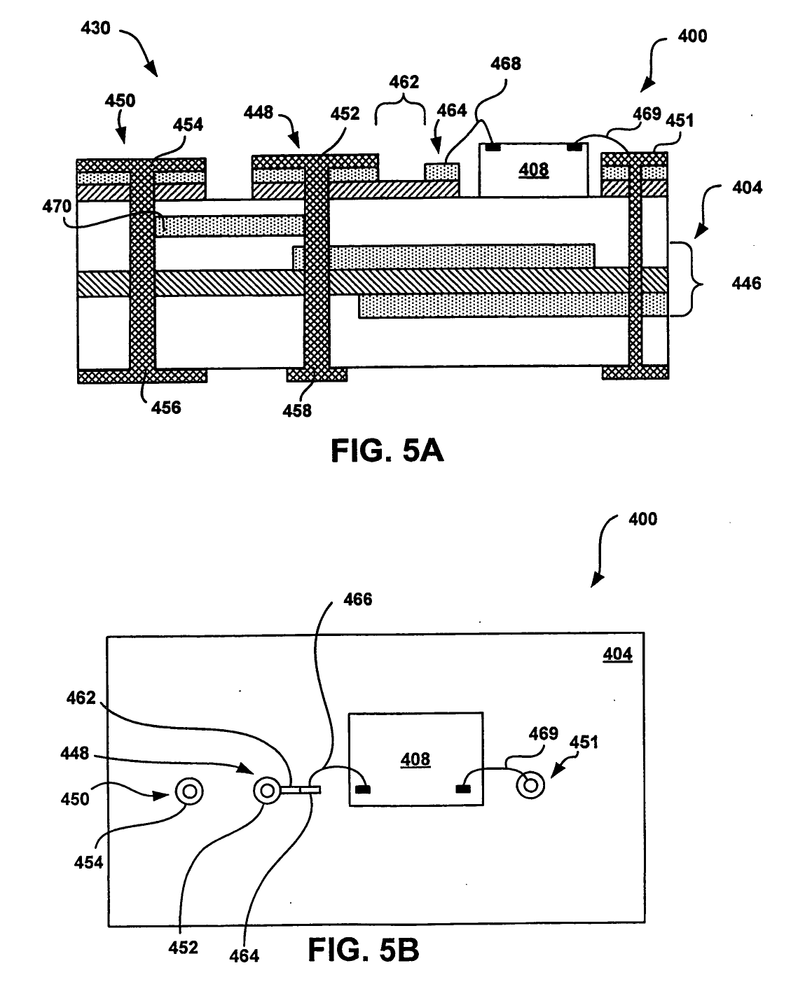

FIGS. 5A-5B illustrate another example of a MEMS assembly 400. The PCB 404 is similar in construction and function as the PCB 304 illustrated in FIGS. 4A-4B, and like elements are referred to using like reference numerals herein, for example 430 and 446 correspond to 330 and 346, respectively.

In this example, an embedded inductor 470 (in series with the wire trace 462 and the embedded capacitor 446) is coupled to the IC 408 to provide a path to ground for undesirable, co-propagating RF noise, which may be conducted on the trace 462 or radiated through free space.

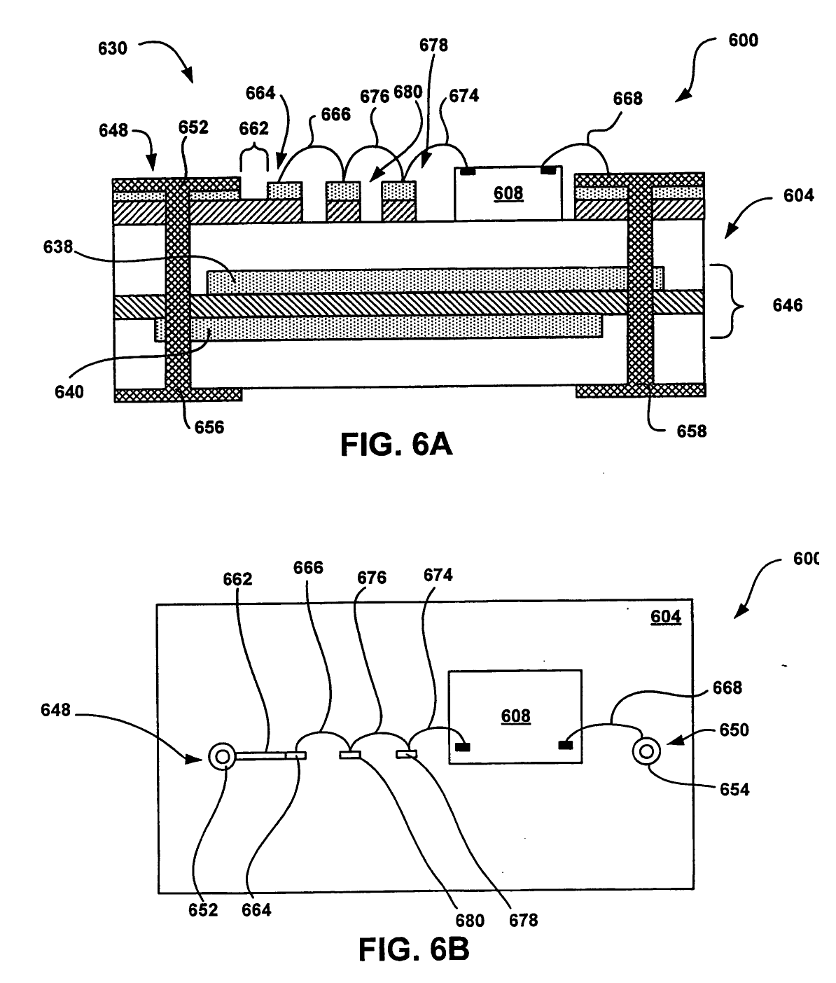

FIGS. 6A-6B illustrate another example of a MEMS assembly 600. The PCB 604 is similar in construction and function as the PCB 204 illustrated in FIGS. 3A-3H, and like elements are referred to using like reference numerals herein, for example 630 and 646 correspond to 230 and 246, respectively.

A plurality of bond wires 666, 674, and 676 and a plurality of bond pads 664, 680, and 678 are connected to the IC 608. More particularly, the bond wire 674 is connected between the IC 608 and bond pad 678. The bond wire 676 is connected between the bond pads 678 and 680, and the bond wire 666 is connected between the bond pads 680 and 664. In doing so, the trace inductance is increased thereby effectively further reducing RF noise, crosstalk, and RFI.

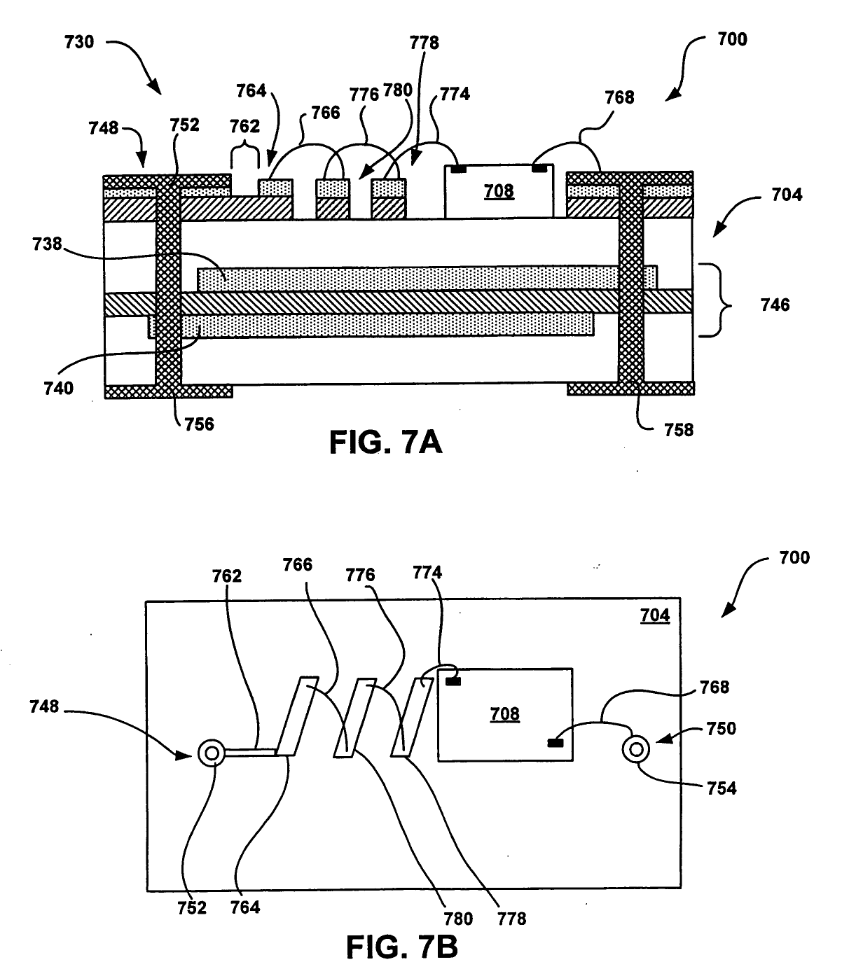

FIGS. 7A-7B illustrate yet another example of a MEMS assembly 700. The PCB 704 is similar in construction and function as the PCB 604 illustrated in FIGS. 6A-6B, and like elements are referred to using like reference numerals herein, for example 730 and 746 correspond to 630 and 646, respectively.

The bond wires 766, 774, and 776 and the bond pads 764, 780, and 778 may be formed in the same fashion as described above except that the bond wires 766, 774, and 776 and the bond pads 764, 680, and 778 are connected substantially in parallel thereby further increasing the inductance of the embedded resistor 730 and thereby effectively further reducing RF noise, crosstalk, and RFI.

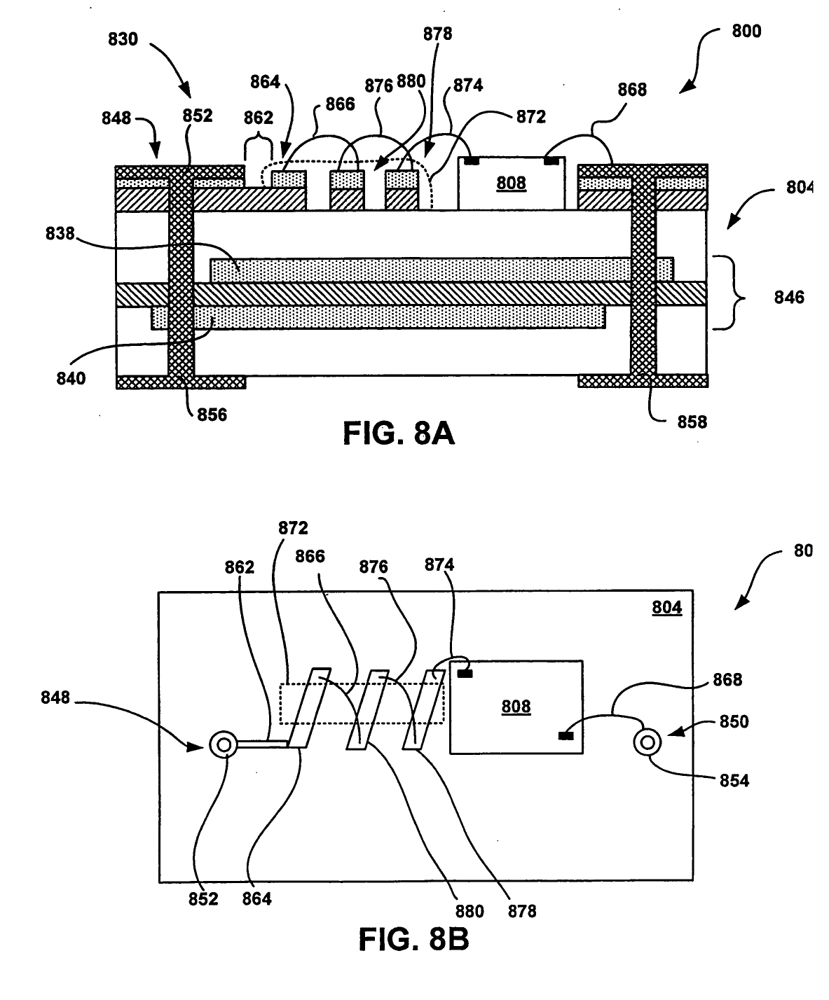

FIGS. 8A-8B illustrate another example of a MEMS assembly 800. The PCB 804 is similar in construction and function as the PCB 704 illustrated in FIGS. 7A-7B, and like elements are referred to using like reference numerals herein, for example 830 and 846 correspond to 730 and 746, respectively.

A highly magnetic-permeability material 872, such as ferrite bead or any other similar type material, is applied to cover part of the bond wires 866, 874, and 876 or to cover the entire conductive surface of the PCB 804 to attenuate unwanted electrical signals, or noise, in the MEMS assembly 800. The coating 872 has a thickness of from about 0.1 to about 100 microns. The coating 872 may be applied by syringe dispensing, spraying, dip-coating, curtain coating, screen or stencil printing, or by any other appropriate means. The through-vias 848 and 850 may be filled with ferrite material (not shown) and together with the coated surface of the substrate 804 constitutes a ferrite loop to attenuate unwanted electrical signals or noise.

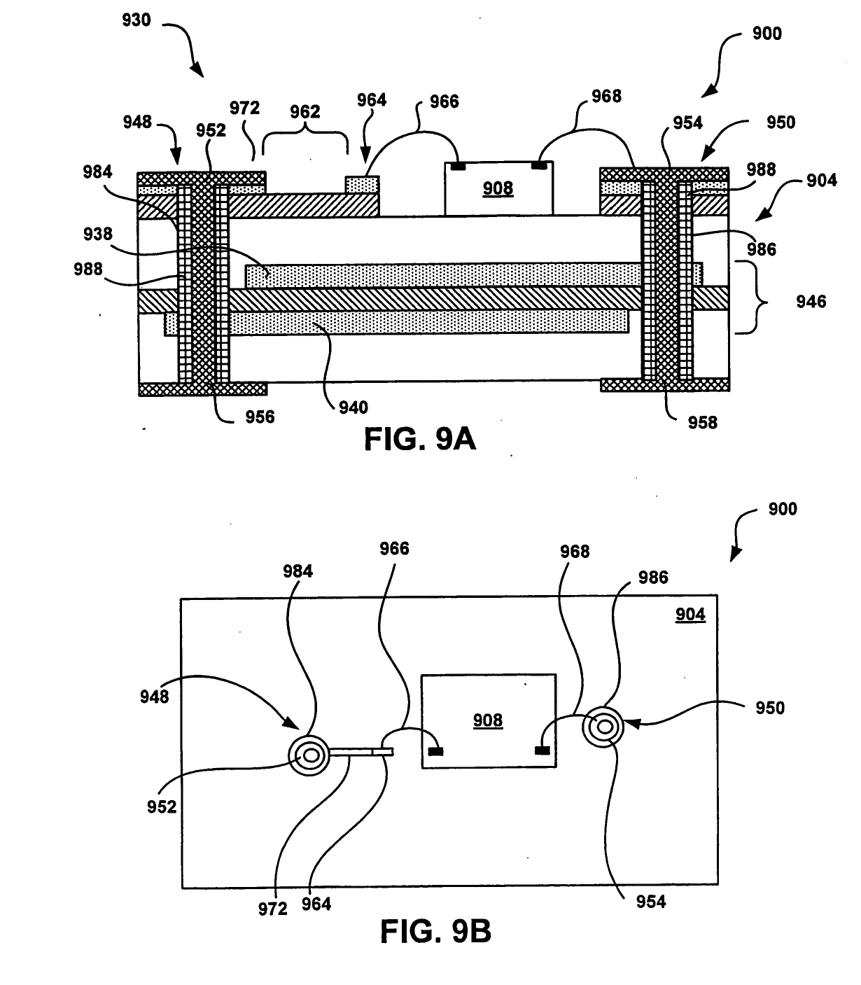

FIGS. 9A-9B illustrate still another example of a MEMS assembly 900. The PCB 904 is similar in construction and function as the PCB 304 illustrated in FIGS. 4A-4B, and like elements are referred to using like reference numerals herein, for example 930 and 946 correspond to 330 and 346, respectively.

A through-via 984 drilled through the PCB 904, may be filled with ferrite material 988. A plated through-via 948 having a dimension smaller than the dimension of the through-vias 984 is drilled through the through-via 984. As shown, the plated through-via 948 is concentric to the through-via 984. An optional through-via (not shown) in close proximity to the combined through-vias 948 and 984 may be provided for routing selective traces or pads to internal conductive layers. Construction in this manner increases the inductance and thereby effectively reduces RF noise, crosstalk, and RFI.

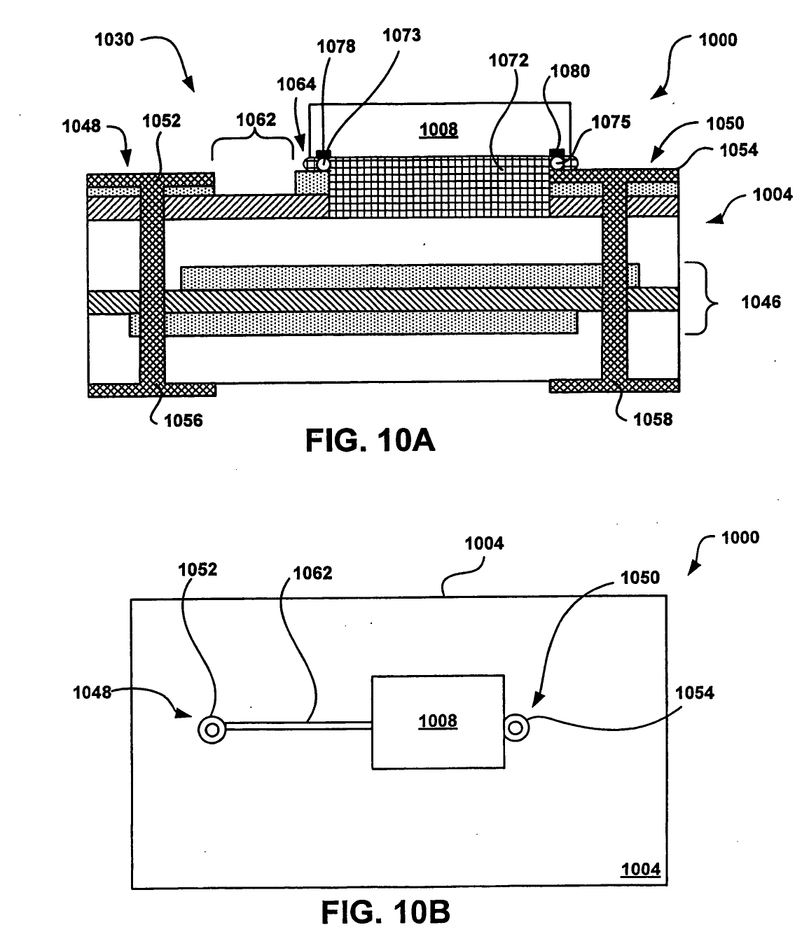

FIGS. 10A-10B illustrate yet another example of a MEMS assembly 1000. The PCB 1004 is similar in construction and function as the PCB 204 illustrated in FIGS. 3A-3H, and like elements are referred to using like reference numerals herein, for example 1030 and 1046 correspond to 230 and 246, respectively.

A plurality of solder balls or bumps 1073 and 1075 may be formed on one surface of the IC 1008 using one of any known bumping procedures is subsequently connected to the IC 1008 to the pads 1054, 1064, defines a gap 1072. The gap 1072 is filled with a high magnetic-permeability material such as ferrite or other similar type material, thereby forming an impedance (e.g. inductor choke that provide high impedance at high frequency). In doing so, the inductance is increased, and thereby effectively reduces RF noise, crosstalk, and RFI.

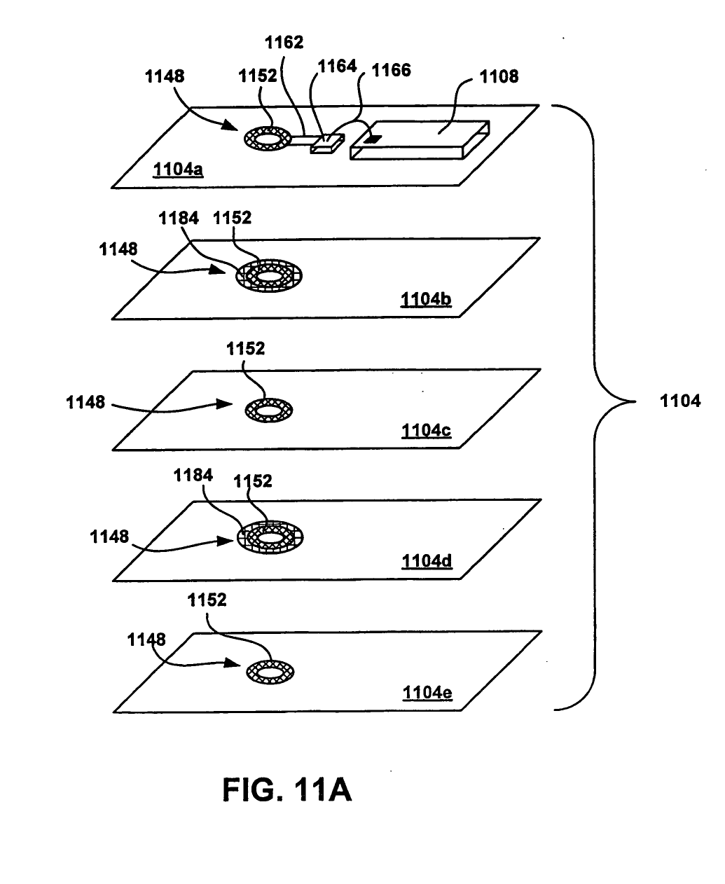

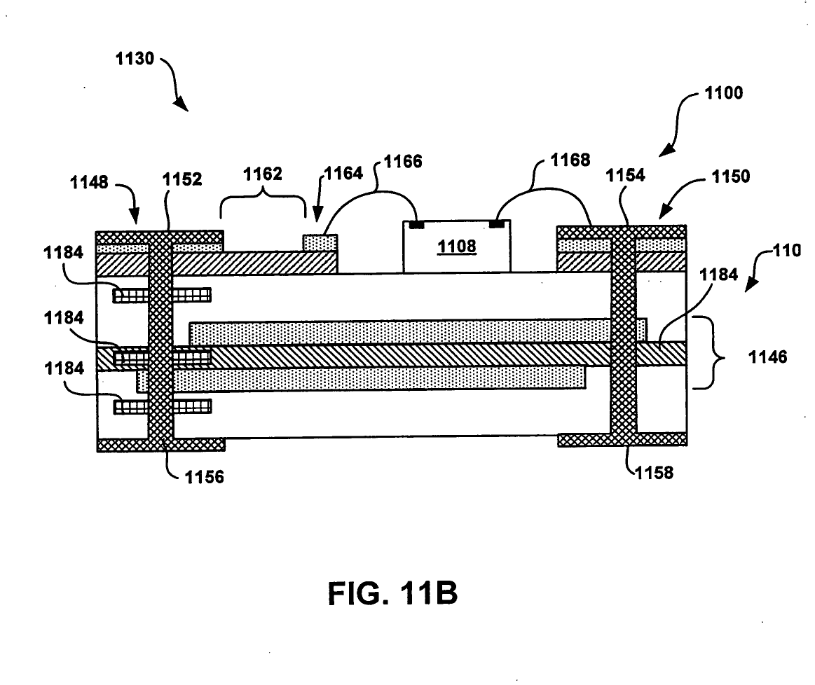

FIGS. 11A-11B illustrate still another example of a MEMS assembly 1100. The PCB 1104 is similar in construction and function as the PCB 204 illustrated in FIGS. 3A-3H, and like elements are referred to using like reference numerals herein, for example, 1130 and 1146 correspond to 230 and 246, respectively.

During multilayer PCB 204 processing (as discussed in FIGS. 3A-3H), a plurality of impedances, such as inductive chokes or ferrite beads in the form of a ring or disc shape is provided on alternate layers 1104b and 1104d of the PCB 1104. In this regard, an inductive choke 1184 may take the form of various shapes with a different number of sizes. At least one plated through-via 1148 for connecting selected traces, pads, or the like, to internal conductive layers or planes, and inductive choke 1184 is drilled through the layers of PCB 1104a, 1104b, 1104c, 104d, and 1104e after the layers are laminated together. As shown, the plated through-via 1148 is concentric to the inductive choke 1184. In do so, the inductance is increased thereby effectively reduces RF noise, crosstalk, and RFI.

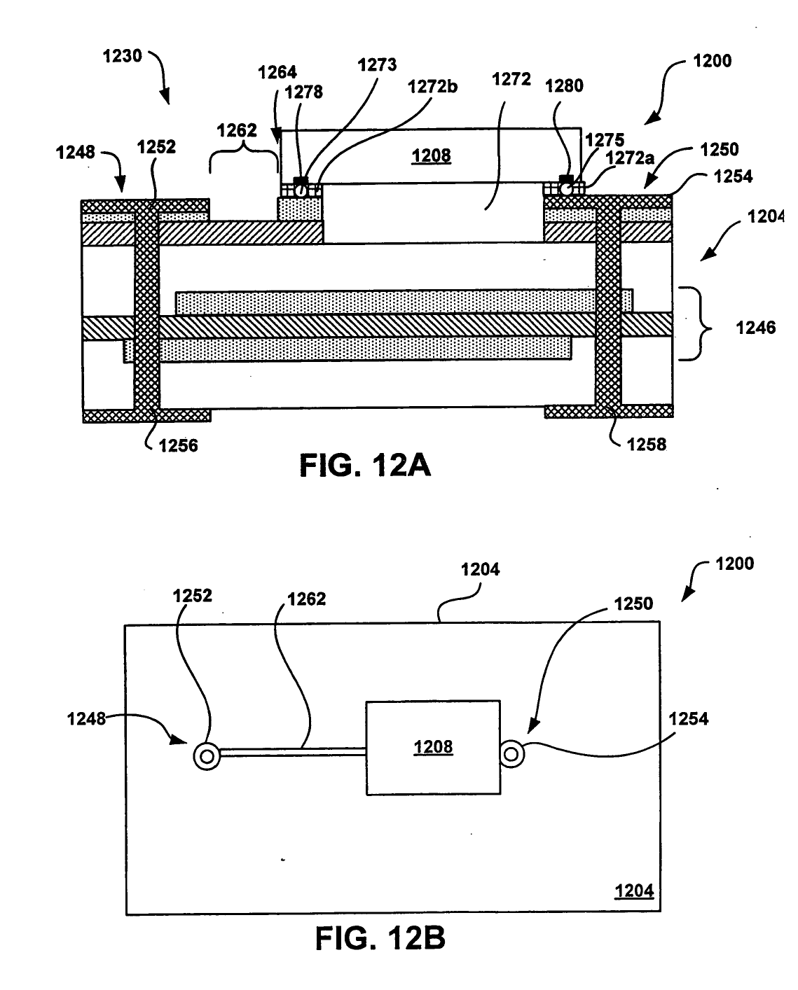

FIGS. 12A-12B illustrate another example of a MEMS assembly 1200. The PCB 1204 is similar in construction and function as the PCB 1004 illustrated in FIGS. 10A-10B, and like elements are referred to using like reference numerals herein, for example 1230 and 1246 correspond to 1030 and 1046, respectively.

Instead of filling the gap 1272 formed between the IC 1208 and the substrate 1204 with ferrite, ferrite beads 1272a and 1272b are provided and surround the solder pads 1275 and 1278 to increase the inductance and thereby effectively reduce RF noise, crosstalk, and RFI.

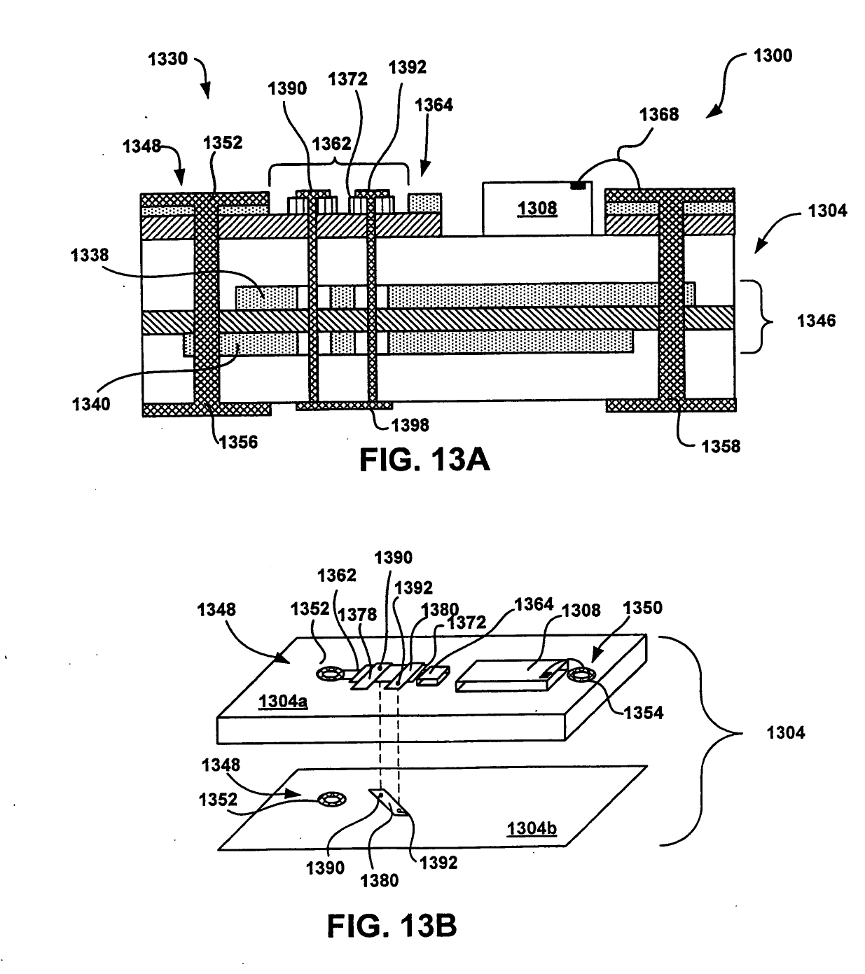

FIGS. 13A-13B illustrate an embedded resistor 1330 and an embedded capacitor 1346 in the PCB 1304 that are used in the MEMS assembly 1300 without the housing 102 and the MEMS microphone 110. The PCB 1304 is similar in construction and function as the PCB 804 illustrated in FIGS. 8A-8B, and like elements are referred to using like reference numerals herein, for example 1330 and 1346 correspond to 830 and 846, respectively.

A series of conductive layers 1378 and 1380 formed on at least two layers 1462 and 1472 (connected by through-vias 1390 and 1392) is formed of a substantially helical pattern which enhances inductance of the signal trace and thereby effectively reduce RF noise, crosstalk, and RFI.

Thus, MEMS assemblies and approaches for manufacturing these assemblies are provided. The assemblies provided have small dimensions and significantly reduce or eliminate the effects of EMI. The small dimensions allow the assemblies to be used in a wide variety of small electronic devices such as such as computers, communication devices, computer-related peripherals, entertainment devices, or listening devices. Since these assemblies are small and easy to manufacture, manufacturing costs are reduced and reliability is enhanced.

While the present invention has been particularly shown and described with reference to particular embodiments thereof, it will be understood by those skilled in the art that various changes may be effected therein without departing from the spirit and scope of the invention as defined by the appended claims.

What is claimed is:

1. A microelectromechanical system (MEMS) assembly comprising:
a MEMS transducer;
an integrated circuit, the integrated circuit being electrically coupled to the MEMS transducer; and
a coupling circuit, the coupling circuit being electrically coupled to the integrated circuit and being adapted to reduce electromagnetic interference (EMI).

2. The MEMS assembly of claim 1, wherein the MEMS transducer is a microphone.

3. The MEMS assembly of claim 1 further comprising a substrate, wherein the substrate comprises a first substrate layer and a second substrate layer attached to the first substrate layer, and wherein each of the first and second substrate layers defines at least one of a conductive layer, an intermediate layer, and a dielectric layer.

4. The MEMS assembly of claim 1, wherein the coupling circuit comprises a low pass filter (LPF) circuit.

5. The MEMS assembly of claim 4, wherein the coupling circuit comprises at least one capacitor.

6. The MEMS assembly of claim 5, wherein the coupling circuit further comprises at least one of: a resistor, a inductor, and a combined resistor and inductor.

7. The MEMS assembly of claim 6, wherein the resistor comprises a resistive foil and the inductor comprises a form selected from a group comprising: a serpentine trace, a spiral trace, helix loop, and a solder ball.

8. The MEMS assembly of claim 3, wherein the substrate comprises a material selected from a group comprising: a printed circuit board, a flexible circuit, a thin film multichip module substrate, and a ceramic substrate.

9. The MEMS assembly of claim 3, wherein the first substrate layer comprises a resistor portion.

10. The MEMS assembly of claim 9, wherein the first substrate layer further comprises an induction portion to increase inductance and reduce radio frequency (RF) noise, crosstalk, and radio frequency interference (RFI).

11. The MEMS assembly of claim 3, wherein the second substrate layer comprises a capacitor portion.

12. The MEMS assembly of claim 3 further comprising a plated through-via having a dimension, the through-via being drilled through the substrate, the through-via being adapted to be connectable.

13. The MEMS assembly of claim 3 further comprising a first through-via having a first dimension, the first through-via being drilled through the first and second substrate layers, the first through-via being adapted to the substrate, the coupling circuit, the integrated circuit and the MEMS transducer.

14. The MEMS assembly of claim 13 further comprising a second through-via drilled through either the first through-via or the first and second substrate layers, wherein the second through-via has a second dimension, the second dimension being smaller than the first dimension of the first through-via.

15. The MEMS assembly of claim 13 further comprising an insulating coating having a high magnetic permeability material adapted to at least partially filled the first through-via.

16. The MEMS assembly of claim 3, wherein the intermediate layer comprises a resistive foil.

17. The MEMS assembly of claim 16, wherein the intermediate layer has a thickness of from about 0.1 to about 200 microns.

18. The MEMS assembly of claim 3, wherein the dielectric layer comprises a solid material selected from the group comprising at least one of: a thermosetting polymer, a thermoplastic polymer, and an inorganic composition.

19. The MEMS assembly of claim 18, wherein the dielectric layer has a thickness of from about 0.1 to about 200 microns.

20. The MEMS assembly of claim 3, wherein an insulating coating having a high magnetic-permeability is adapted to at least partially cover at least one of: the first substrate layer, the second substrate layer, the coupling circuit, the integrated circuit, and the MEMS transducer.

21. The MEMS assembly of claim 20, wherein the insulating coating is a ferrite.

22. The MEMS assembly of claim 21, wherein the insulating coating has a thickness of from about 0.1 to about 100 microns.

23. A microelectromechanical system (MEMS) assembly comprising:
a substrate having a first substrate layer and a second substrate layer; and
a coupling circuit, the coupling circuit being electrically coupled to at least one of the first substrate layer and the second substrate layer.

24. The MEMS assembly of claim 23, wherein the coupling circuit comprises a low pass filter (LPF) circuit.

25. The MEMS assembly of claim 24, wherein the coupling circuit comprises at least one capacitor.

26. The MEMS assembly of claim 25, wherein the coupling circuit further comprises at least one element selected from a group comprising: a resistor, an inductor, and a combined resistor and inductor, the coupling circuit being electrically coupled to the at least one capacitor.

27. The MEMS assembly of claim 26, wherein the resistor comprises a wire trace and the inductor comprises a form selected from a group comprising:
a serpentine trace, a spiral wire, a helix loop, and a solder ball.

28. The MEMS assembly of claim 23, wherein each of the first and second substrate layers comprises at least one of a conductive layer, an intermediate layer, and a dielectric layer.

29. The MEMS assembly of claim 28 further comprising an insulating coating having a high magnetic-permeability, the coating being adapted to at least partially cover at least one of: the first substrate layer, the second substrate layer and the coupling circuit.

30. The MEMS assembly of claim 29, wherein the insulating coating is a ferrite.

31. The MEMS assembly of claim 30, wherein the insulating coating has a thickness of from about 0.1 to about 100 microns.

32. The MEMS assembly of claim 23, wherein the substrate comprises an element selected from a group comprising: a printed circuit board, a flexible circuit, a thin film multichip module substrate, and a ceramic substrate.

33. The MEMS assembly of claim 23, wherein the substrate further comprises at least one surface mounted device, the surface mounted device comprising at least one device selected from a group comprising: an integrated circuit, and a microelectromechanical system (MEMS) transducer.

34. The MEMS assembly of claim 33 further comprising a first through-via having a first dimension, the first through-via being drilled through the substrate, the through-via being adapted to interconnect the surface mounted device and the coupling circuit to the substrate.

35. The MEMS assembly of claim 34 further comprising a second through-via drilled through either the first through-via or the substrate, wherein the second through-via has a second dimension, the second dimension being smaller than the first dimension of the first through-via.

36. The MEMS assembly of claim 34 further comprising an insulating coating having a high magnetic permeability material adapted to at least partially fill the first through-via.

37. The MEMS assembly of claim 28, wherein the intermediate layer comprises a resistive foil.

38. The MEMS assembly of claim 37, wherein the intermediate layer has a thickness of from about 0.1 to about 200 microns.

39. The MEMS assembly of claim 28, wherein the dielectric layer comprises a solid material selected from the group comprising at least one of a thermosetting polymer, a thermoplastic polymer, and an inorganic composition.

40. The MEMS assembly of claim 39, wherein the dielectric layer has a thickness of from about 0.1 to about 200 microns.

41. A method of manufacturing a microelectromechanical system (MEMS) assembly comprising:
providing a coupling circuit, the coupling circuit having a capacitor portion and a conductor portion;
coupling a surface mounted device to the coupling circuit; and
providing a substrate, the substrate for coupling the coupling circuit to ground undesirable co-propagating radio frequency (RF) and allowing direct current (DC) or low frequency signals to pass through the surface mounted device.

42. The method of claim 41, wherein the conductor portion comprises at least one element selected from a group comprising: a resistor, an inductor, and a combined resistor and inductor, and wherein the conductor portion is electrically coupled to the capacitor portion.

43. The method of claim 42, wherein the coupling circuit comprises a low pass filter (LPF).

44. The method of claim 41 further comprising:
providing a first substrate layer, the first substrate layer being disposed on a second substrate layer, wherein each of the first and second substrate layers comprises at least one of a conductive layer, an intermediate layer, and a dielectric layer.

45. The method of claim 44 further comprising:
disposing an insulating coating to completely or partially cover at least one of: the first substrate layer, the second substrate layer, the coupling circuit, and a surface mounted device.

46. The method of claim 45 further comprising:
drilling a first through-via through the substrate layers, the through-via being adapted to interconnect the surface mounted device and the coupling circuit to the substrate layers;
drilling a second through-via either through the first through-via or the substrate layers; and
depositing the insulating coating to the first through-via.

47. The method of claim 42, wherein the resistor comprises a resistive foil and the inductor comprises a form selected from a group comprising: a serpentine trace, a spiral trace, a helix loop, and a solder ball.

48. The method of claim 41, wherein the substrate comprises a material selected from the group comprising: a printed circuit board, a flexible circuit, a thin film multichip module substrate, and a ceramic substrate.

49. The method of claim 44, wherein the intermediate layer comprises a resistive foil.

50. The method of claim 49, wherein the intermediate layer has a thickness of from about 0.1 to about 200 microns.

51. The method of claim 44, wherein the dielectric layer comprises at least one solid material selected from a group comprising: a thermosetting polymer, a thermopolastic polymer, and an inorganic composition.

52. The method of claim 51, wherein the dielectric layer has a thickness of from about 0.1 to about 200 microns.

53. The method of claim 45, wherein the insulating coating is a ferrite.

54. The method of claim 53, wherein the insulating coating has a thickness of from about 0.1 to about 100 microns.
